(19) United States
(12) Patent Application Publication
(10) Pub. No.: US 2003/0038347 A1
(43) Pub. Date: Feb. 27, 2003

(54) Stackable-type semiconductor package

(75) Inventors: Jansen Chiu, kaohsiung (TW); Chien-Hung Lai, Kaohsiung (TW)

Correspondence Address: DOUGHERTY & TROXELL, SUITE 1404, 5205 LEESBURG PIKE, FALLS CHURCH, VA, 22041, US

(73) Assignee: Walton Advanced Electronics LTD

(21) Appl. No.: 09/933,756

(22) Filed: Aug. 22, 2001

(51) Int. Cl. H01L 23/02

(52) U.S. Cl. 257/678

(57) ABSTRACT

A semiconductor package includes a die, a package body, a plurality of leads, and a plurality of metal bonding wires. The upper surface and the lower surface of the lead are exposed outside the package body for being electrically outer stacking and adhering terminals. The semiconductor packages are stacked each other by conductive materials formed on the upper surfaces and the lower surfaces of leads. This semiconductor package is non-leaded, and whose size and packaging thickness are decreased, thus it is suitable for high-density surface mounting and stacking.

### FIELD OF THE INVENTION

The present invention is relating to a stackable type semiconductor package, particularly to a semiconductor package without outer leads. The semiconductor package includes a plurality of leads, each lead having an upper surface and a lower surface exposed outside the package body for stack mounting.

### BACKGROUND OF THE INVENTION

A common semiconductor package 100 had been brought up from U.S. Pat. No. 6,146,919 “package stack via bottom leaded plastic (BLP) packaging”. As shown in FIG. 1, the semiconductor package 100 comprises a die 110, a package body 120, a plurality of leads 140, and a plurality of metal conductive wires 150.

As shown in FIG. 1, the semiconductor package 100 is a stackable-type BLP (bottom leaded plastic) package, wherein the die 110 is adhered on the partial upper surfaces of inner leads 141 of the leads 140 by the tapes 130 to form the interior construction of COL (chip-over-lead). The die 110 has an upper surface 111 and a lower surface 112 thereon forming a plurality of bonding pads 113. The bonding pads 113 are electrically connected to the lower surfaces of corresponding inner leads 141 by metal conductive wires 150. The die 110, the metal conductive wires 150, and the inner leads 141 are sealed by a package body 120 made from an insulating and thermosetting resin for protecting the die 110 from the injury of hostile environment. The outer leads 143 of the plurality of leads 140 are exposed outside the package body 120, and with an inverted-J type. It is necessary that the bending portion of each lead 140 is higher than the upper surface 160 of the semiconductor package 100. The connection surfaces 142 of the plurality of leads 140 are formed on the lower surface 170 of the semiconductor package 100, and exposed outside the package body 120. Each connection surface 142 electrically connects with another semiconductor device, printed circuit board or other electrical apparatuses. As shown in FIG. 1, when several semiconductor packages 100 are stacked and combined, the connection surfaces 142 and the outer leads 143 are used for stack electrical connection. Although the stack of semiconductor devices is accomplished by the method mentioned above, the semiconductor package 100 has a big size and a thick packaging thickness, and the interval H1 between two stacked semiconductor devices is wider so that the thickness will be increased while stacking.

### SUMMARY

The object of this invention is to provide a stackable-type semiconductor package. The upper surface and the lower surface of leads are exposed outside the package body for being electrically outer connecting terminals of the stackable semiconductor package. The semiconductor package is non-leaded extending outside and suitable for a high-density surface mounting, and it has a small size, a thin packaging thickness, and a narrow interval between two stacked semiconductor devices. The memory capacity would be increased by means of stacking of the semiconductor packages.

The stackable-type semiconductor package in accordance with the present invention comprises:

a package body;

a die inside the package body, having an upper surface, a lower surface, and a

plurality of bonding pads formed at the perimeters of the upper surface of the die;

a plurality of leads, each lead having an upper surface, a lower surface which are

exposed outside the package body, and a supporting portion extending to the lower surface of the die for attaching the die; and

a plurality of metal conductive wires sealed inside the package body, the wires electrically connecting the bonding pads of die with corresponding leads.

### DESCRIPTION OF THE DRAWINGS

FIG. 1 is a cross-sectional view of a semiconductor package disclosed in U.S. Pat. No. 6,146,919 “package stack via bottom leaded plastic (BLP) packaging”.

FIG. 2 is a cross-sectional view of a stackable-type semiconductor package in accordance with the first embodiment of the present invention.

FIG. 3 is a stacked cross-sectional view of a plurality of stackable-type semiconductor packages in accordance with the first embodiment of the present invention.

FIG. 4 is a stacked cross-sectional view of a plurality of stackable-type semiconductor packages in accordance with the second embodiment of the present invention.

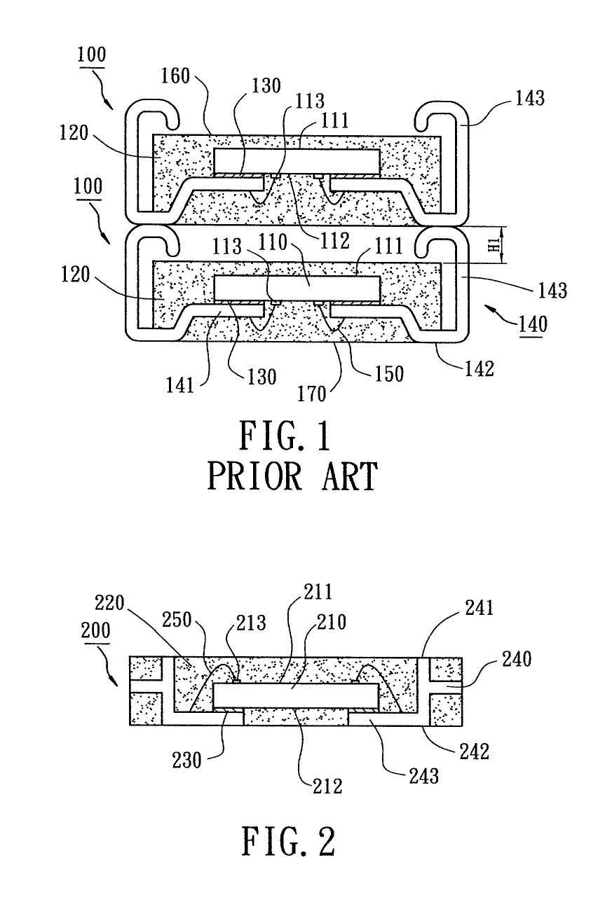

### DETAILED DESCRIPTION OF THE PRESENT INVENTION

With reference to the drawings attached, the present invention will be described by means of the embodiments below.

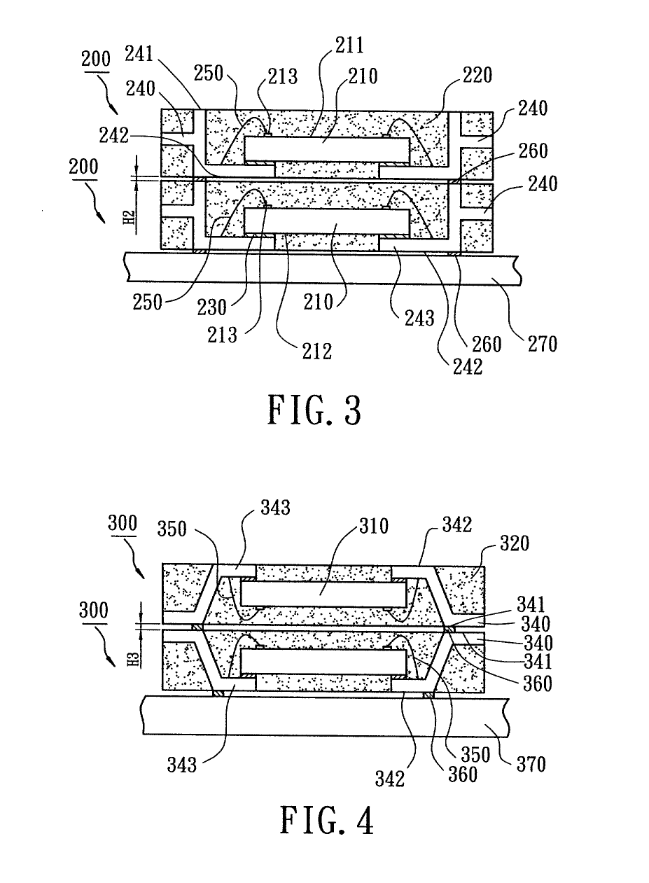

In the first embodiment of the present invention, FIG. 2 is a cross-sectional view of a stackable-type semiconductor package 200, FIG. 3 is a stacked cross-sectional view of several semiconductor packages 200. As shown in FIG. 2, the semiconductor package 200 comprises a die 210, a package body 220, a plurality of leads 240, and a plurality of metal conductive wires 250.

The die 210 is made of silicon, gallium arsenide or other semiconductor materials. It can be one kind of memory chips such as DRAM, SRAM, flash, DDR or Rambus, etc or microprocessor, logic chip, or radio frequency chip etc. The die 210 has an upper surface 211 and a lower surface 212. It is familiar that a plurality of bonding pads 213 and integrated circuit elements (not shown in the drawing) are formed on the upper surface 211 of die 210. A semiconductor package includes a die 210 sealed by a package body 220 of insulating thermosetting resin for protecting from the injury of hostile environment.

The leads 240 are derived from a lead frame, each lead 240 has a supporting portion 243. The lower surface 212 of the die 210 is adhered on the supporting portions 243 by double-sided tapes 230. Each lead 240 has an upper surface 241 and a lower surface 242 which are exposed outside the package body 220 for being electrically outer connecting terminals of the stackable semiconductor package 200. The metal conductive wires 250 sealed in the package body 220 electrically connect the bonding pads 213 of die 210 with leads 240.

As shown in FIG. 2, the leads 240 of this embodiment are formed by half-etching method, and with a bend-type. In the packaging process, the package body 220 of unsetting epoxy resin is formed by molding method, and then fills the bending portions of leads 240 for increasing the bonding strength of leads 240 connected to the semiconductor package 200.

As shown in FIG. 3, the semiconductor packages 200 are stacked and adhered by the conductive materials 260 such as conductive epoxy, conductive solder paste, or conductive resin, etc. The lower surfaces 242 of leads 240 of the upper semiconductor package 200 are adhered on the upper surfaces 241 of leads 240 of the lower semiconductor package 200 by the conductive materials 260, and the lower surfaces 242 of leads of the lower semiconductor package 200 are adhered on the printed circuit board 270 by the conductive materials 260 to form a vertical stack configuration.

In the second embodiment of the present invention, FIG. 4 is a cross-sectional view of two stackable-type semiconductor packages 300 in stack configuration. Some components of the semiconductor package 300 are as the same as those of the stackable-type semiconductor package of the first embodiment, such as the die 300, the metal conductive wires 350, and the package body 320 etc, but it is different that the leads 340 are formed by stamping method. The leads 340 are bend-type, each lead 340 has a supporting portion 343, and the dies 310 are adhered on the supporting portions 343. In the packaging process, the package body 320 of unsetting epoxy resin is formed by molding method and covers the bending portions of leads 340 for increasing the bonding strength of leads 340 connected to the semiconductor package 300. The semiconductor package 300 is stacked and adhered by the conductive materials 360 such as conductive epoxy, conductive solder paste, or conductive resin, etc. The upper semiconductor package 300 is inverted, so that upper surfaces 341 of leads 340 of the upper semiconductor package 300 are adhered on the upper surfaces 341 of leads 340 of the lower semiconductor package 300 by the conductive materials 360 (i.e. the two stacks of semiconductor packages 300 need to be turned over each other for stacking). Then the lower surfaces 342 of leads 340 of the lower semiconductor package 300 are adhered on the printed circuit board 370 to form a vertical stacked type.

The semiconductor package 200 of the first embodiment and the semiconductor package 300 of the second embodiment are non-leaded and suitable for high-density surface mounting. Because the semiconductor package 200, 300 has no die pad and outer lead, whose size and packaging thickness are decreased. The intervals H2 and H3 of two stacks of semiconductor devices are decreased (i.e. H2<H1, H3<H1). The memory capacity would be increased by means of stacking the semiconductor packages.

The above description of embodiments of this invention is intended to be illustrative and not limiting. Other embodiments of this invention will be obvious to those skilled in the art in view of the above disclosure.

What is claimed is:

1. A semiconductor package comprising:
a package body;
a die inside the package body, the die having an upper surface, a lower surface, and a plurality of bonding pads formed at the perimeters of the upper surface;
a plurality of leads, each lead having an upper surface, a lower surface which are exposed outside the package body, and a supporting portion extending onto the lower surface of the die for adhering the die; and
a plurality of metal bonding wires sealed inside the package body and electrically connecting the bonding pads of the die with the corresponding leads.

2. The semiconductor package in accordance with claim 1, wherein each lead has a half-etching portion.

3. The semiconductor package in accordance with claim 1, wherein each lead has a stamp-bending portion.

4. The semiconductor package in accordance with claim 1, further comprising conductive materials formed on the upper surfaces or the lower surfaces of the leads.
